(19) United States
(12) Patent Application Publication
(10) Pub. No.: US 2013/0020578 A1
(43) Pub. Date: Jan. 24, 2013

(54) Semiconductor Device and Method for Manufacturing the Same

(71) Applicants: Qingqing Liang, Lagrangeville, NY (US); Huilong Zhu, Poughkeepsie, NY (US); Huicai Zhong, San Jose, CA (US)

(72) Inventors: Qingqing Liang, Lagrangeville, NY (US); Huilong Zhu, Poughkeepsie, NY (US); Huicai Zhong, San Jose, CA (US)

(21) Appl. No.: 13/521,998

(22) PCT Filed: Nov. 30, 2011
(86) PCT No.: PCT/CN11/02000

§ 371 Date: Jul. 12, 2012

(30) Foreign Application Priority Data
Jul. 20, 2011 (CN) 201110203389.6

(51) Int. Cl. H01L 29/786; H01L 21/336

(52) U.S. Cl. 257/66; 438/156; 257/E29.293; 257/E21.413

(57) ABSTRACT

The invention relates to a semiconductor device and a method for manufacturing such a semiconductor device. A semiconductor device according to an embodiment of the invention may comprise: an active fin region which is arranged on an insulating layer; a threshold voltage adjusting layer arranged on top of the active fin region, which threshold voltage adjusting layer is used to adjust the threshold voltage of the semiconductor device; a gate stack which is arranged on the threshold voltage adjusting layer, on the sidewalls of the active fin region and on the insulating layer, and comprises a gate dielectric and a gate electrode formed on the gate dielectric; and a source region and a drain region formed in the active fin region on both sides of the gate stack respectively. The semiconductor device according to the invention comprises the threshold voltage adjusting layer which may adjust the threshold voltage of the semiconductor device. This provides a simple and convenient way capable of adjusting the threshold voltage of a semiconductor device comprising an active fin region.

### FIELD OF THE INVENTION

The invention relates to a semiconductor device. More particularly, the invention relates to a semiconductor device comprising an active fin region. The invention also relates to a method for manufacturing such a semiconductor device.

### BACKGROUND OF THE INVENTION

With the development of semiconductor technology, a semiconductor device comprising an active fin region, for example, a fin-typed field effect transistor (Finfet), appears. For the next generation of very large scale integrated circuit (VLSI) technology, a semiconductor device comprising an active fin region such as Finfet is a very promising semiconductor device.

However, how to adjust the threshold voltage of a semiconductor device comprising an active fin region is a very challenging technical problem. Especially for a CMOS Finfet comprising a high-k metal gate, the adjustment of the threshold voltage becomes more difficult. In order to adjust the threshold voltages of an N-typed field effect transistor (NFET) and a P-typed field effect transistor (PFET) to reach the required values, it is usually necessary to form different metal electrodes on the NFET and the PFET. However, such a process makes it not easy to control the height of the gate at the boundaries of the NFET and the PFET, leading to a lower yield.

Therefore, there is a need for a simple solution capable of adjusting the threshold voltage of a semiconductor device comprising an active fin region.

### SUMMARY OF THE INVENTION

An object of the invention is to overcome at least some of the above drawbacks and provide an improved semiconductor device and a method for manufacturing the same.

According to an aspect of the invention, there is provided a semiconductor device. The semiconductor device may comprise an active fin region which is arranged on an insulating layer; a threshold voltage adjusting layer arranged on top of the active fin region, which threshold voltage adjusting layer is used to adjust the threshold voltage of the semiconductor device; a gate stack which is arranged on the threshold voltage adjusting layer, on the sidewalls of the active fin region and on the insulating layer, and comprises a gate dielectric and a gate electrode formed on the gate dielectric; and a source region and a drain region formed in the active fin region on both sides of the gate stack respectively.

According to another aspect of the invention, there is provided a method for manufacturing a semiconductor device. The method may comprise providing a substrate, which substrate comprises an insulating layer and a semiconductor layer arranged on the insulating layer; forming a threshold voltage adjusting layer on the semiconductor layer, which threshold voltage adjusting layer is used to adjust the threshold voltage of the semiconductor device; patterning the threshold voltage adjusting layer and the semiconductor layer, thereby forming an active fin region located on the insulating layer; forming a gate dielectric layer and a gate electrode layer located on the gate dielectric layer; patterning the gate electrode layer, the gate dielectric layer and the threshold voltage adjusting layer, thereby forming a gate stack which is arranged on the threshold voltage adjusting layer, on the sidewalls of the active fin region and on the insulating layer; and forming a source region and a drain region in the active fin region on both sides of the gate stack respectively.

According to yet another aspect of the invention, there is provided a method for manufacturing a semiconductor device. The method may comprise providing a substrate, which substrate comprises an insulating layer and a semiconductor layer arranged on the insulating layer; forming a threshold voltage adjusting layer on the semiconductor layer, which threshold voltage adjusting layer is used to adjust the threshold voltage of the semiconductor device; patterning the threshold voltage adjusting layer and the semiconductor layer, thereby forming an active fin region located on the insulating layer; forming a dummy gate stack which is arranged on the threshold voltage adjusting layer, on the sidewalls of the active fin region and on the insulating layer; forming a source region and a drain region in the active fin region on both sides of the dummy gate stack respectively; removing the dummy gate stack; and forming a gate stack which is arranged on the threshold voltage adjusting layer, on the sidewalls of the active fin region and on the insulating layer, and comprises a gate dielectric and a gate electrode formed on the gate dielectric.

### BRIEF DESCRIPTION OF THE DRAWINGS

These and other objects, features and advantages of the invention will become more apparent from the following detailed description of the exemplary embodiments of the invention with reference to the accompanying drawings. In the drawings:

FIG. 1 shows a semiconductor device according to an exemplary embodiment of the invention, wherein FIG. 1(a) is a stereogram of the semiconductor device, and FIG. 1(b) is a cross-section view of the semiconductor device of FIG. 1(a) along the line B-B;

FIG. 2 shows a semiconductor device according to another exemplary embodiment of the invention, wherein FIG. 2(a) is a stereogram of the semiconductor device, and FIG. 2(b) is a cross-section view of the semiconductor device of FIG. 2(a) along the line B-B;

FIGS. 3-8 show the schematic views of the individual steps of a method for manufacturing a semiconductor device according to an exemplary embodiment of the invention;

FIGS. 9-15 show the schematic views of the individual steps of a method for manufacturing a semiconductor device according to another exemplary embodiment of the invention.

### DETAILED DESCRIPTION OF THE INVENTION

Exemplary embodiments of the invention will be described in detail with reference to the accompanying drawings hereinafter. The drawings are schematic and not drawn to scale, and just for illustrating the embodiments of the invention and are not intended to limit the protective scope of the invention. In the drawings, like reference numerals denote identical or similar components. For making the technical solution of the invention clearer, process steps and device structures known in the art are omitted herein.

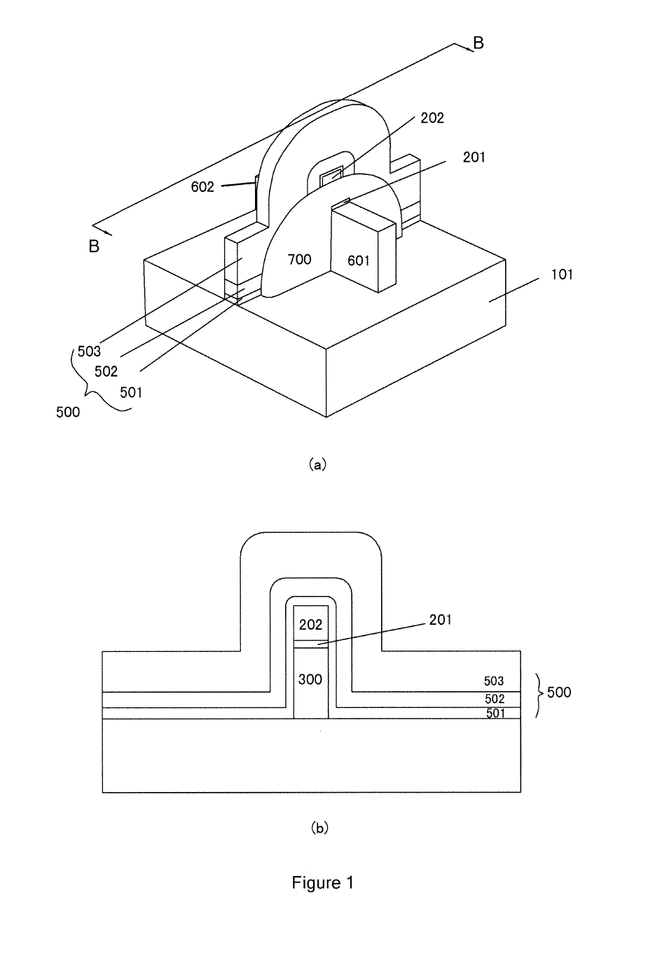

Firstly, a semiconductor device according to an exemplary embodiment of the invention will be described in detail with reference to FIG. 1. FIG. 1(a) is a stereogram of the semiconductor device, and FIG. 1(b) is a cross-section view of the semiconductor device of FIG. 1(a) along the line B-B.

As shown in FIG. 1, the semiconductor device according to an exemplary embodiment of the invention comprises an active fin region 300 which is arranged on an insulating layer 101, a threshold voltage adjusting layer 202 arranged on top of the active fin region 300 for adjusting the threshold voltage of the semiconductor device, a gate stack 500, and a source region 601 and a drain region 602. The gate stack 500 is arranged on the threshold voltage adjusting layer 202, on the sidewalls of the active fin region 300 and on the insulating layer 101, and comprises a gate dielectric 501 and a gate electrode 502 formed on the gate dielectric 501. The source region 601 and the drain region 602 are formed in the active fin region on both sides of the gate stack 500 respectively. In the semiconductor device as shown in FIG. 1, the structures on both sides of the gate stack 500 may be symmetric.

The insulating layer 101 may comprise, but not limited to, a material or a combination of materials selected from a group made up of the following materials: silicon dioxide, silicon nitride, etc. The active fin region 300 may comprise a semiconductor material. As an example, the gate dielectric 501 of the gate stack 500 may comprise a high-k dielectric material, and the gate electrode 502 may comprise a metal.

As shown in FIG. 1, the semiconductor device according to an exemplary embodiment of the invention comprises the threshold voltage adjusting layer 202. The threshold voltage of the semiconductor device may be adjusted by the threshold voltage adjusting layer. This provides a simple and convenient way capable of adjusting the threshold voltage of a semiconductor device comprising an active fin region. The threshold voltage adjusting layer 202 may comprise a material for adjusting the threshold voltage of a semiconductor device. For example, the material for forming the threshold voltage adjusting layer 202 may comprise a rare earth element (La, Er, Sc, Y, Ce, Pr, Nd, Pm, Sm, Eu, Gd, Tb, Dy, Ho, Tm, Yb, Lu), Sr, Al, Ga, In, Tl, or any other element for adjusting the threshold voltage. In an example, the threshold voltage adjusting layer 202 may be an insulating material. The insulating material may for example comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ, Al₂O₃, Ga₂O₃, InOₓ, TlOₓ. For a different type of semiconductor device, a different threshold voltage adjusting layer may be formed. For example, in the case of the semiconductor device being an N-typed field effect transistor, the threshold voltage adjusting layer 202 may comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ; in the case of the semiconductor device being a P-typed field effect transistor, the threshold voltage adjusting layer 202 may comprise, but not limited to, a material or a combination of materials selected from a group made up of the following materials: Al₂O₃, Ga₂O₃, InOₓ, TlOₓ.

Optionally, as shown in FIG. 1, the semiconductor device according to an exemplary embodiment of the invention may further comprise a buffer layer 201 arranged between the top of the active fin region 300 and the threshold voltage adjusting layer 202. The buffer layer 201 may for example comprise an insulating material. Where the semiconductor device comprises the buffer layer 201, the threshold voltage adjusting layer 202 may for example be made from a metallic material. The metallic material may for example comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr, Al, Ga, In, Tl. As mentioned previously, for a different type of semiconductor device, a different threshold voltage adjusting layer may be formed. For example, in the case of the semiconductor device being an N-typed field effect transistor, the threshold voltage adjusting layer 202 may comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr; in the case of the semiconductor device being a P-typed field effect transistor, the threshold voltage adjusting layer 202 may comprise, but not limited to, a material or a combination of materials selected from a group made up of the following materials: Al, Ga, In, Tl.

Optionally, as shown in FIG. 1, the gate stack 500 of the semiconductor device according to an exemplary embodiment of the invention may further comprise a semiconductor layer 503 formed on the gate electrode 502. The semiconductor layer 503 may for example comprise polysilicon. Where the gate electrode 502 comprises a metal, the semiconductor layer 503 may prevent oxygen from entering the metal gate electrode.

Optionally, as shown in FIG. 1, the semiconductor device according to an exemplary embodiment of the invention may further comprise a spacer isolation layer 700 formed on both sides of the gate stack 500, on the top and the sidewalls of the active fin region respectively.

Optionally, the semiconductor device according to an exemplary embodiment of the invention may further comprise a base layer (now shown) located below the insulating layer 101. The base layer may for example be formed from a semiconductor material.

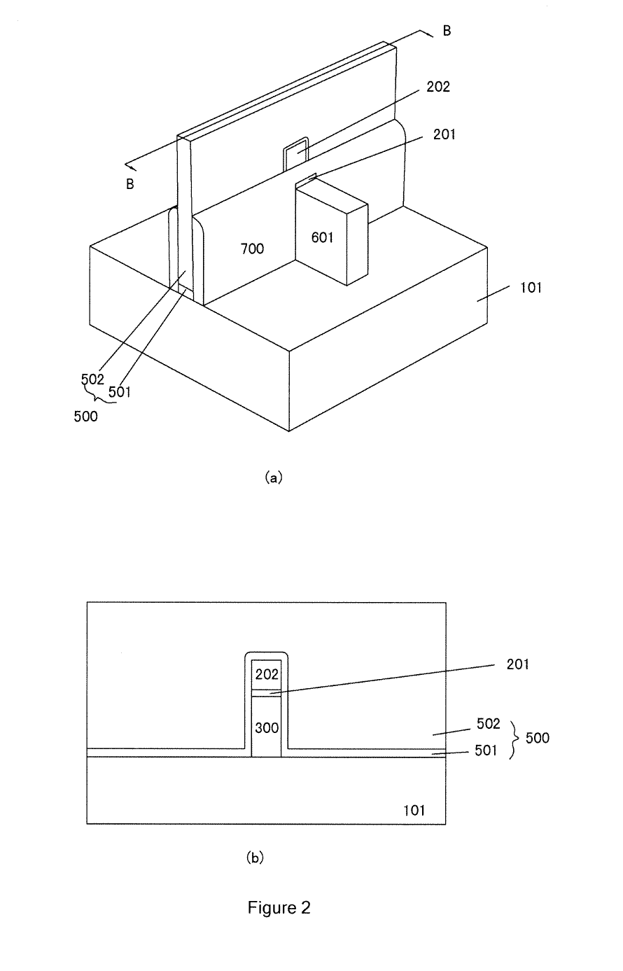

FIG. 2 shows a semiconductor device according to another exemplary embodiment of the invention. Therein FIG. 2(a) is a stereogram of the semiconductor device, and FIG. 2(b) is a cross-section view of the semiconductor device of FIG. 2(a) along the line B-B.

As compared to the situation in FIG. 1 in which the gate stack is roughly conformally arranged on the threshold voltage adjusting layer, on the sidewalls of the active fin region and on the insulating layer, the shape of the gate stack in FIG. 2 is different.

As shown in FIG. 2, the semiconductor device according to another exemplary embodiment of the invention comprises an active fin region 300 which is arranged on an insulating layer 101, a threshold voltage adjusting layer 202 arranged on top of the active fin region 300 for adjusting the threshold voltage of the semiconductor device, a gate stack 500, and a source region and a drain region. In the semiconductor device as shown in FIG. 2, the structures on both sides of the gate stack 500 may be symmetric. Therefore, in FIG. 2(a), the source region 601 located on one side of the gate stack 500 is shown, while the drain region located on the other side of the gate stack 500 is not shown.

The gate stack 500 is arranged on the threshold voltage adjusting layer 202, on the sidewalls of the active fin region 300 and on the insulating layer 101, and comprises a gate dielectric 501 and a gate electrode 502 formed on the gate dielectric 501. The source region and the drain region are formed in the active fin region on both sides of the gate stack 500 respectively.

The insulating layer 101 may comprise, but not limited to, a material or a combination of materials selected from a group made up of the following materials: silicon dioxide, silicon nitride, etc. The active fin region 300 may comprise a semiconductor material. As an example, the gate dielectric 501 of the gate stack 500 may comprise a high-k dielectric material, and the gate electrode 502 may comprise a metal.

As shown in FIG. 2, the semiconductor device according to an exemplary embodiment of the invention comprises the threshold voltage adjusting layer 202. The threshold voltage of the semiconductor device may be adjusted by the threshold voltage adjusting layer, which provides a simple and convenient way capable of adjusting the threshold voltage of a semiconductor device comprising an active fin region. The threshold voltage adjusting layer 202 may comprise a material for adjusting the threshold voltage of a semiconductor device. For example, the material for forming the threshold voltage adjusting layer 202 may comprise a rare earth element (La, Er, Sc, Y, Ce, Pr, Nd, Pm, Sm, Eu, Gd, Tb, Dy, Ho, Tm, Yb, Lu), Sr, Al, Ga, In, Tl, or any other element for adjusting the threshold voltage. In an example, the threshold voltage adjusting layer 202 may be an insulating material. The insulating material may for example comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ, Al₂O₃, Ga₂O₃, InOₓ, TlOₓ. For a different type of semiconductor device, a different threshold voltage adjusting layer may be formed. For example, in the case of the semiconductor device being an N-typed field effect transistor, the threshold voltage adjusting layer 202 may comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ; in the case of the semiconductor device being a P-typed field effect transistor, the threshold voltage adjusting layer 202 may comprise, but not limited to, a material or a combination of materials selected from a group made up of the following materials: Al₂O₃, Ga₂O₃, InOₓ, TlOₓ.

Optionally, as shown in FIG. 2, the semiconductor device according to an exemplary embodiment of the invention may further comprise a buffer layer 201 arranged between the top of the active fin region 300 and the threshold voltage adjusting layer 202. The buffer layer 201 may for example comprise an insulating material. Where the semiconductor device comprises the buffer layer 201, the threshold voltage adjusting layer 202 may for example be made from a metallic material. The metallic material may for example comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr, Al, Ga, In, Tl. As mentioned previously, for a different type of semiconductor device, a different threshold voltage adjusting layer may be formed. For example, in the case of the semiconductor device being an N-typed field effect transistor, the threshold voltage adjusting layer 202 may comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr; in the case of the semiconductor device being a P-typed field effect transistor, the threshold voltage adjusting layer 202 may comprise, but not limited to, a material or a combination of materials selected from a group made up of the following materials: Al, Ga, In, Tl.

Optionally, as shown in FIG. 2, the semiconductor device according to an exemplary embodiment of the invention may further comprise a spacer isolation layer 700 formed on both sides of the gate stack 500, on the top and the sidewalls of the active fin region respectively.

Optionally, the semiconductor device according to an exemplary embodiment of the invention may further comprise a base layer (now shown) located below the insulating layer 101. The base layer may for example be formed from a semiconductor material.

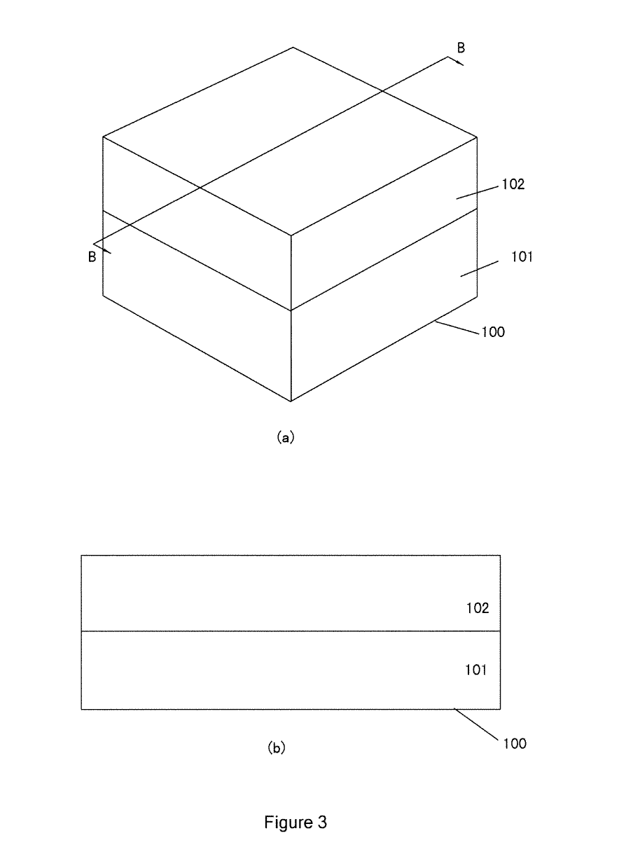

In the following, a method for manufacturing a semiconductor device according to an exemplary embodiment of the invention will be described in detail with reference to FIGS. 3-8.

FIG. 3 shows a schematic view of the first step of a method for manufacturing a semiconductor device according to an exemplary embodiment of the invention. Therein FIG. 3(a) is a stereogram, and FIG. 3(b) is a cross-section view along the line B-B.

As shown in FIG. 3, a substrate 100 is provided. The substrate 100 may comprise an insulating layer 101 and a semiconductor layer 102 arranged on the insulating layer 101. As an example, the insulating layer 101 may comprise, but not limited to, a material or a combination of materials selected from a group made up of the following materials: silicon dioxide, silicon nitride, etc. The semiconductor layer 102 may comprise, but not limited to, a material or a combination of materials selected from a group made up of the following materials: silicon, germanium, etc.

Optionally, the substrate 100 may further comprise a base layer (now shown) located below the insulating layer 101. The base layer may for example be formed from a semiconductor material.

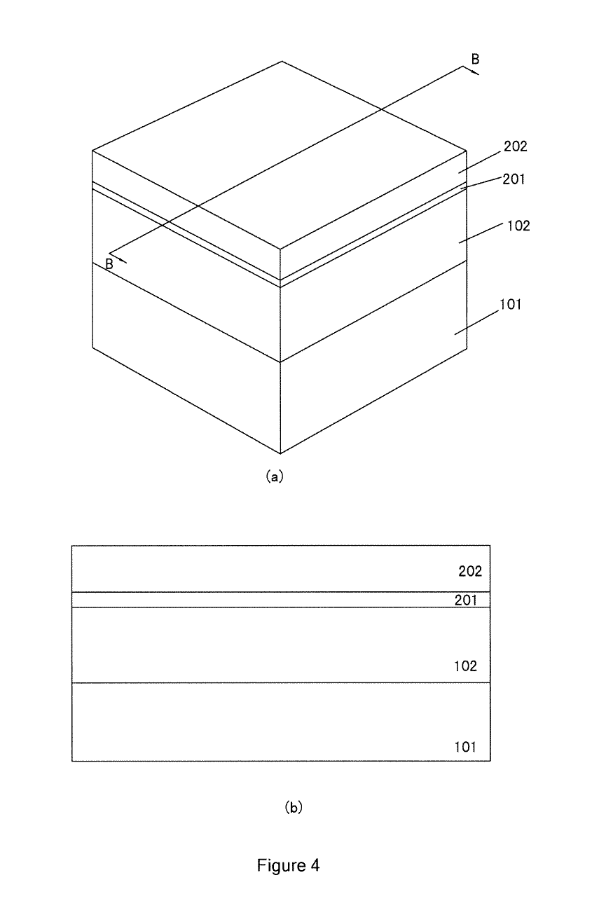

FIG. 4 shows a schematic view of the second step of the method for manufacturing a semiconductor device according to an exemplary embodiment of the invention. Therein FIG. 4(a) is a stereogram, and FIG. 4(b) is a cross-section view along the line B-B.

As shown in FIG. 4, on the semiconductor layer 102 is formed a threshold voltage adjusting layer 202 for adjusting the threshold voltage of the semiconductor device. The threshold voltage adjusting layer 202 may comprise a material for adjusting the threshold voltage of a semiconductor device. For example, the material for forming the threshold voltage adjusting layer 202 may comprise a rare earth element (La, Er, Sc, Y, Ce, Pr, Nd, Pm, Sm, Eu, Gd, Tb, Dy, Ho, Tm, Yb, Lu), Sr, Al, Ga, In, Tl, or any other element for adjusting the threshold voltage. In an example, the threshold voltage adjusting layer 202 may be an insulating material. The insulating material may for example comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ, Al₂O₃, Ga₂O₃, InOₓ, TlOₓ. For a different type of semiconductor device, a different threshold voltage adjusting layer may be formed. For example, in the case of the semiconductor device to be formed being an N-typed field effect transistor, the threshold voltage adjusting layer 202 may comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ; in the case of the semiconductor device to be formed being a P-typed field effect transistor, the threshold voltage adjusting layer 202 may comprise, but not limited to, a material or a combination of materials selected from a group made up of the following materials: Al₂O₃, Ga₂O₃, InOₓ, TlOₓ.

Optionally, before the threshold voltage adjusting layer 202 is formed, a buffer layer 201 may be formed on the semiconductor layer 102. The buffer layer 201 may for example comprise an insulating material. Where the semiconductor device comprises the buffer layer 201, the threshold voltage adjusting layer 202 may for example be made from a metallic material. The metallic material may for example comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr, Al, Ga, In, Tl. As mentioned previously, for a different type of semiconductor device, a different threshold voltage adjusting layer may be formed. For example, in the case of the semiconductor device to be formed being an N-typed field effect transistor, the threshold voltage adjusting layer 202 may comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr; in the case of the semiconductor device to be formed being a P-typed field effect transistor, the threshold voltage adjusting layer 202 may comprise, but not limited to, a material or a combination of materials selected from a group made up of the following materials: Al, Ga, In, Tl.

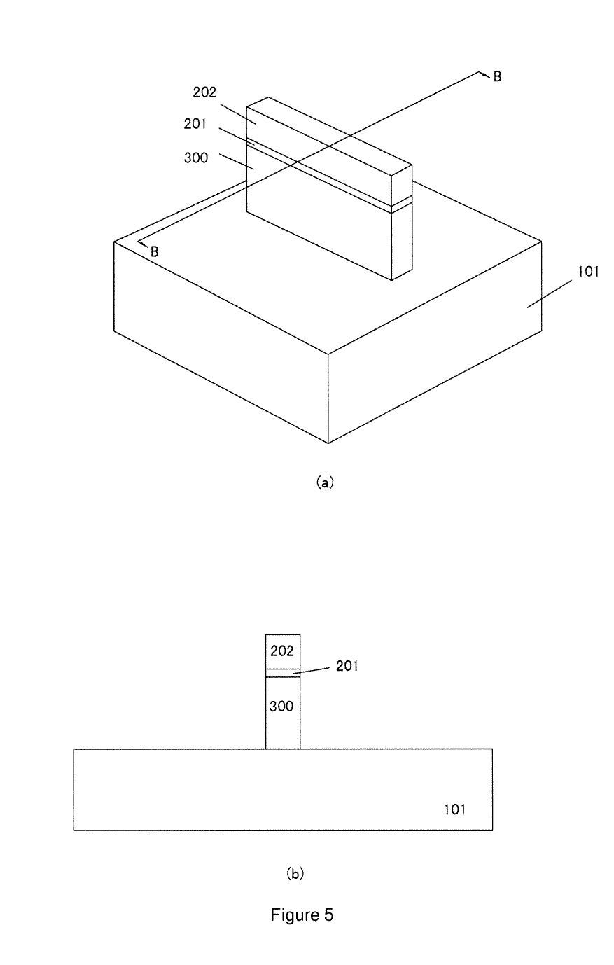

FIG. 5 shows a schematic view of the third step of the method for manufacturing a semiconductor device according to an exemplary embodiment of the invention. Therein FIG. 5(a) is a stereogram, and FIG. 5(b) is a cross-section view along the line B-B.

As shown in FIG. 5, the threshold voltage adjusting layer 202 and the semiconductor layer are patterned, thereby forming an active fin region 300 located on the insulating layer 101.

In an example, this may be achieved by first etching the threshold voltage adjusting layer 202 so as to pattern it, and then etching the semiconductor layer using the patterned threshold voltage adjusting layer 202 as a mask. However, the invention is not limited thereto, and the threshold voltage adjusting layer and the semiconductor layer may be patterned so as to form an active fin region by any other process known to those skilled in the art.

Where there is a buffer layer 201 formed on the semiconductor layer, further the buffer layer 201 is patterned in the step of forming an active fin region shown in FIG. 5.

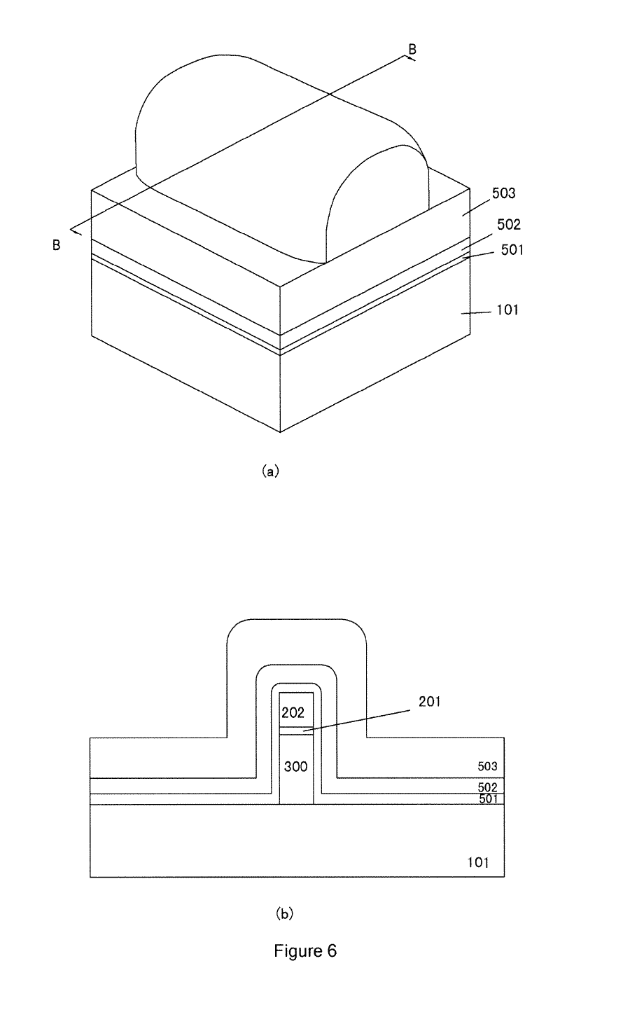

FIG. 6 shows a schematic view of the fourth step of the method for manufacturing a semiconductor device according to an exemplary embodiment of the invention. Therein FIG. 6(a) is a stereogram, and FIG. 6(b) is a cross-section view along the line B-B.

As shown in FIG. 6, a gate dielectric layer 501 and a gate electrode layer 502 located on the gate dielectric layer 501 are formed. The gate dielectric layer 501 and the gate electrode layer 502 may cover the outer surfaces of the active fin region 300 and the threshold voltage adjusting layer 202 as well as the upper surface of the insulating layer 101. As an example, the gate dielectric layer 501 may comprise a high-k dielectric material, and the gate electrode layer 502 may comprise a metal.

In an example, the gate dielectric layer 501 and the gate electrode layer 502 may be formed by deposition. However, the invention is not limited thereto, and the gate dielectric layer and the gate electrode layer may also be formed by any other process known to those skilled in the art.

Optionally, as shown in FIG. 6, a further semiconductor layer 503 may also be formed on the gate electrode layer 502 after the gate dielectric layer 501 and the gate electrode layer 502 located on the gate dielectric layer 501 are formed. The further semiconductor layer 503 may for example comprise polysilicon.

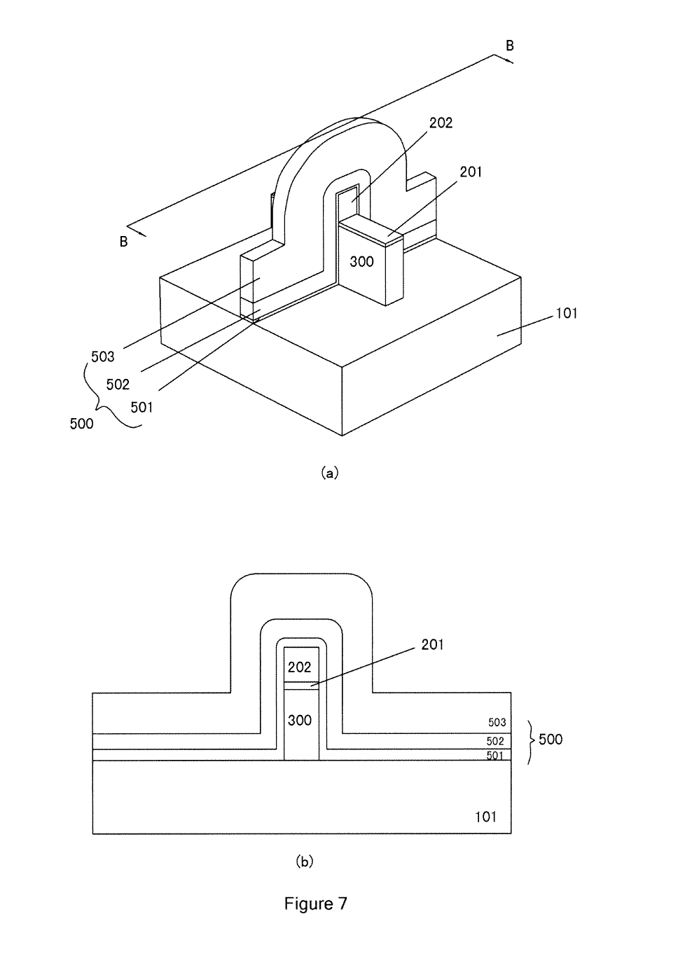

FIG. 7 shows a schematic view of the fifth step of the method for manufacturing a semiconductor device according to an exemplary embodiment of the invention. Therein FIG. 7(a) is a stereogram, and FIG. 7(b) is a cross-section view along the line B-B.

As shown in FIG. 7, the gate electrode layer 502, the gate dielectric layer 501 and the threshold voltage adjusting layer 202 are patterned, thereby forming a gate stack 500. The gate stack 500 is arranged on the threshold voltage adjusting layer 202, on the sidewalls of the active fin region 300 and on the insulating layer 101.

In an example, this may be achieved by first etching the gate electrode layer 502 so as to pattern it, then etching the gate dielectric layer 501 using the patterned gate electrode layer 502 as a mask, and then etching threshold voltage adjusting layer 202 using the patterned gate electrode layer 502 and the gate dielectric layer 501 as a mask. However, the invention is not limited thereto, and the gate electrode layer, the gate dielectric layer, and the threshold voltage adjusting layer may be patterned by any other process known to those skilled in the art.

Where there is a further semiconductor layer 503 formed on the gate electrode layer 502, further the further semiconductor layer 503 is patterned in the step of forming a gate stack shown in FIG. 7.

Optionally, a thermal annealing may further be performed after the gate stack 500 is formed. The thermal annealing may for example be done at a temperature of 900 to 1000. By performing the thermal annealing, the atoms or ions of the material for adjusting the threshold voltage of the semiconductor device in the threshold voltage adjusting layer may further be driven into the gate dielectric layer, thereby facilitating adjusting the threshold voltage of the semiconductor device.

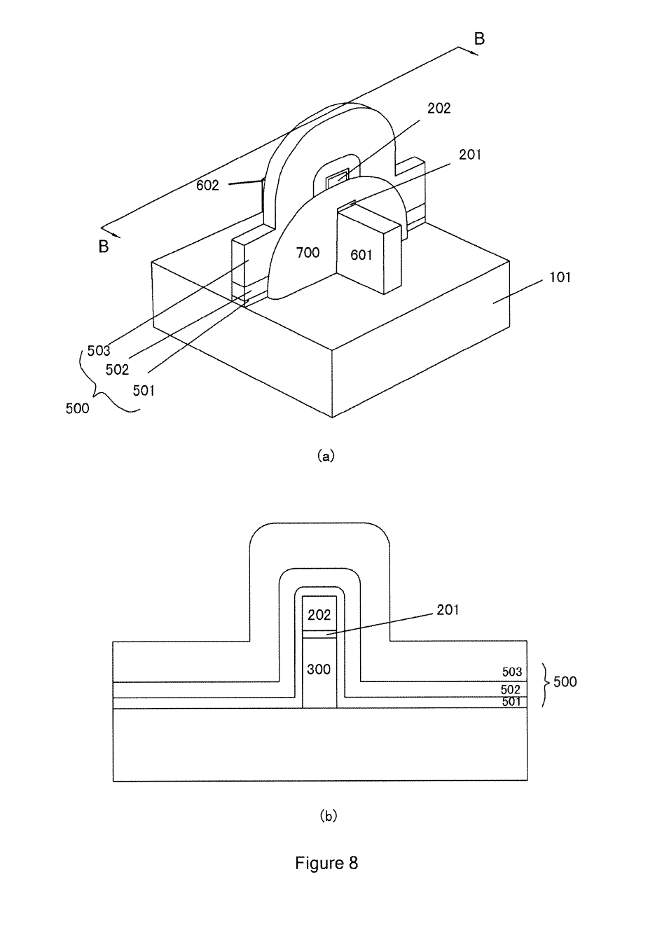

FIG. 8 shows a schematic view of the sixth step of the method for manufacturing a semiconductor device according to an exemplary embodiment of the invention. Therein FIG. 8(a) is a stereogram, and FIG. 8(b) is a cross-section view along the line B-B.

As shown in FIG. 8, a source region 601 and a drain region 602 are formed in the active fin region on both sides of the gate stack 500 respectively. In the semiconductor device shown in FIG. 8, the structures on both sides of the gate stack 500 may be symmetric.

In an example, the source region 601 and the drain region 602 may be formed by injecting ions into the active fin region on both sides of the gate stack 500 respectively. However, the invention is not limited thereto, and the source region and the drain region may also be formed by any other process known to those skilled in the art.

Where a buffer layer 201 is formed, optionally, the buffer layer 201 on the part of the active fin region in which the source region and the drain region are to be formed may be removed before the source region and the drain region are formed.

Optionally, a spacer isolation layer 700 may be formed on both sides of the gate stack 500, on the top and the sidewalls of the active fin region respectively before the source region 601 and the drain region 602 are formed. Where a buffer layer 201 is formed, optionally, the buffer layer 201 on the part of the active fin region in which the source region and the drain region are to be formed may be removed after the spacer isolation layer 700 is formed.

Through the method as shown in FIGS. 3-8, a semiconductor device according to an exemplary embodiment of the invention is made, which comprises a threshold voltage adjusting layer. Through the threshold voltage adjusting layer, the threshold voltage of the semiconductor device may be adjusted, which provides a simple and convenient way capable of adjusting the threshold voltage of a semiconductor device comprising an active fin region.

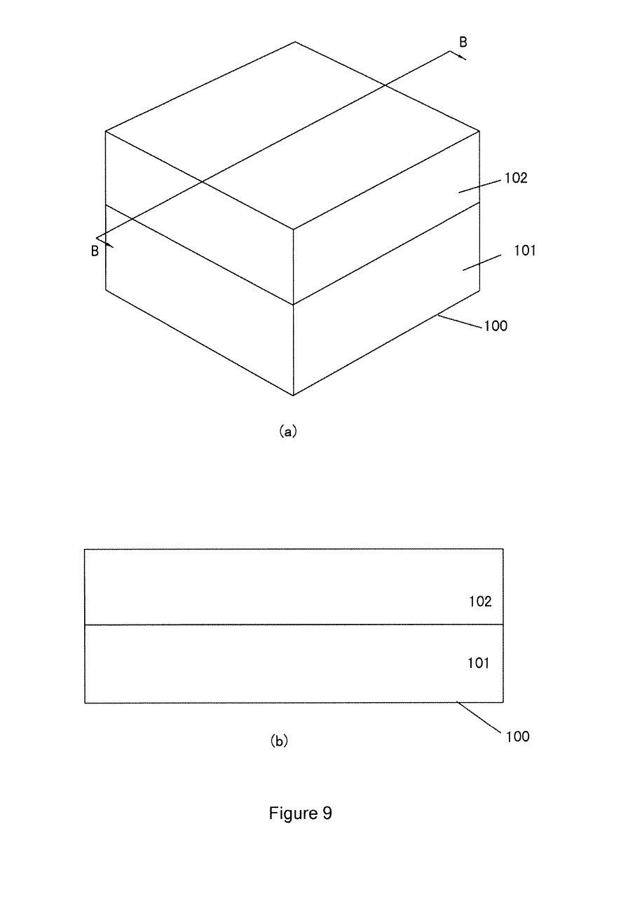

In the following, a method for manufacturing a semiconductor device according to another exemplary embodiment of the invention will be described in detail with reference to FIGS. 9-15.

FIG. 9 shows a schematic view of the first step of a method for manufacturing a semiconductor device according to another exemplary embodiment of the invention. Therein FIG. 9(a) is a stereogram, and FIG. 9(b) is a cross-section view along the line B-B.

As shown in FIG. 9, a substrate 100 is provided. The substrate 100 may comprise an insulating layer 101 and a semiconductor layer 102 arranged on the insulating layer 101. As an example, the insulating layer 101 may comprise, but not limited to, a material or a combination of materials selected from a group made up of the following materials: silicon dioxide, silicon nitride, etc. The semiconductor layer 102 may comprise, but not limited to, a material or a combination of materials selected from a group made up of the following materials: silicon, germanium, etc.

Optionally, the substrate 100 may further comprise a base layer (now shown) located below the insulating layer 101. The base layer may for example be formed from a semiconductor material.

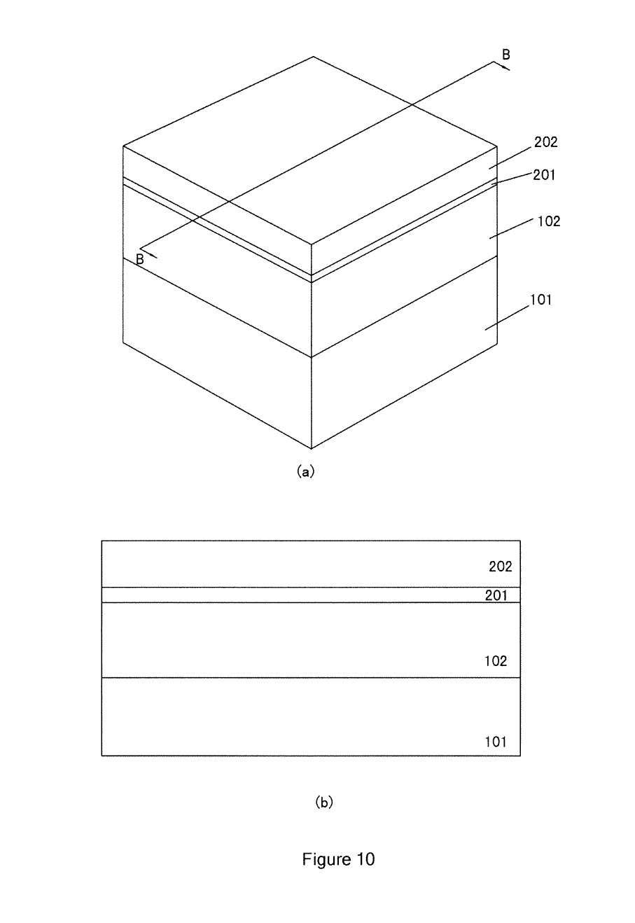

FIG. 10 shows a schematic view of the second step of the method for manufacturing a semiconductor device according to another exemplary embodiment of the invention. Therein FIG. 10(a) is a stereogram, and FIG. 10(b) is a cross-section view along the line B-B.

As shown in FIG. 10, on the semiconductor layer 102 is formed a threshold voltage adjusting layer 202 for adjusting the threshold voltage of the semiconductor device. The threshold voltage adjusting layer 202 may comprise a material for adjusting the threshold voltage of a semiconductor device. For example, the material for forming the threshold voltage adjusting layer 202 may comprise a rare earth element (La, Er, Sc, Y, Ce, Pr, Nd, Pm, Sm, Eu, Gd, Tb, Dy, Ho, Tm, Yb, Lu), Sr, Al, Ga, In, Tl, or any other element for adjusting the threshold voltage. In an example, the threshold voltage adjusting layer 202 may be an insulating material. The insulating material may for example comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ, Al₂O₃, Ga₂O₃, InOₓ, TlOₓ. For a different type of semiconductor device, a different threshold voltage adjusting layer may be formed. For example, in the case of the semiconductor device to be formed being an N-typed field effect transistor, the threshold voltage adjusting layer 202 may comprise, but not limited to, a material or a combination of materials selected from a group made up of the following materials: LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ; in the case of the semiconductor device to be formed being a P-typed field effect transistor, the threshold voltage adjusting layer 202 may comprise, but not limited to, a material or a combination of materials selected from a group made up of the following materials: Al₂O₃, Ga₂O₃, InOₓ, TlOₓ.

Optionally, before the threshold voltage adjusting layer 202 is formed, a buffer layer 201 may be formed on the semiconductor layer 102. The buffer layer 201 may for example comprise an insulating material. Where the semiconductor device comprises the buffer layer 201, the threshold voltage adjusting layer 202 may for example be formed from a metallic material. The metallic material may for example comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr, Al, Ga, In, Tl. As mentioned previously, for a different type of semiconductor device, a different threshold voltage adjusting layer may be formed. For example, in the case of the semiconductor device to be formed being an N-typed field effect transistor, the threshold voltage adjusting layer 202 may comprise, but not limited to, a material or a combination of materials selected from a group made up of the following materials: La, Er, Sc, Y, Ce, Pr, Nd, Pm, Sm, Eu, Gd, Tb, Dy, Ho, Tm, Yb, Lu, Sr; in the case of the semiconductor device to be formed being a P-typed field effect transistor, the threshold voltage adjusting layer 202 may comprise, but not limited to, a material or a combination of materials selected from a group made up of the following materials: Al, Ga, In, Tl.

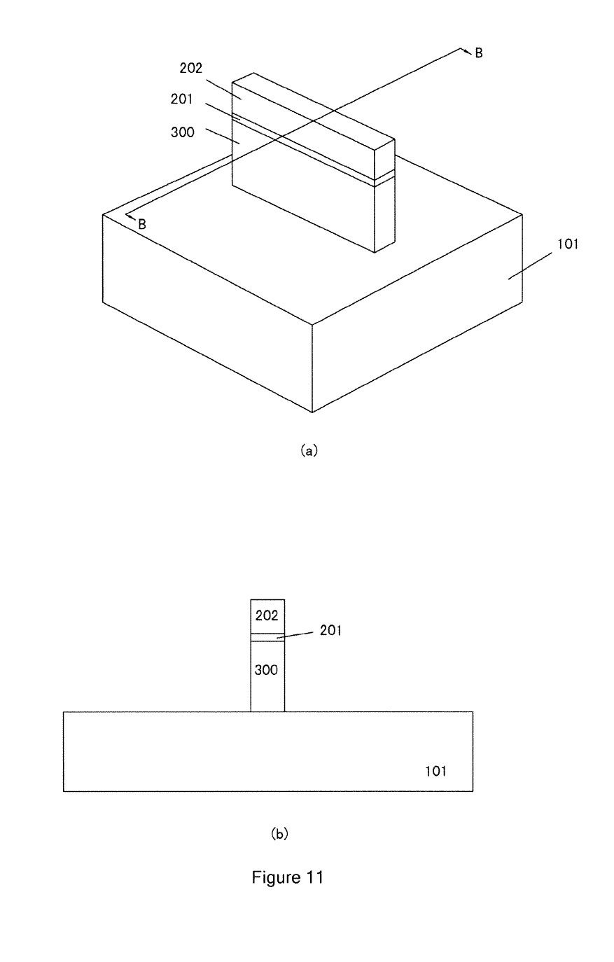

FIG. 11 shows a schematic view of the third step of the method for manufacturing a semiconductor device according to another exemplary embodiment of the invention. Therein FIG. 11(a) is a stereogram, and FIG. 11(b) is a cross-section view along the line B-B.

As shown in FIG. 11, the threshold voltage adjusting layer 202 and the semiconductor layer are patterned, thereby forming an active fin region 300 located on the insulating layer 101.

In an example, this may be achieved by first etching the threshold voltage adjusting layer 202 so as to pattern it, and then etching the semiconductor layer using the patterned threshold voltage adjusting layer 202 as a mask. However, the invention is not limited thereto, and the threshold voltage adjusting layer and the semiconductor layer may be patterned so as to form an active fin region by any other process known to those skilled in the art.

Where there is a buffer layer 201 formed on the semiconductor layer, further the buffer layer 201 is patterned in the step of forming an active fin region shown in FIG. 11.

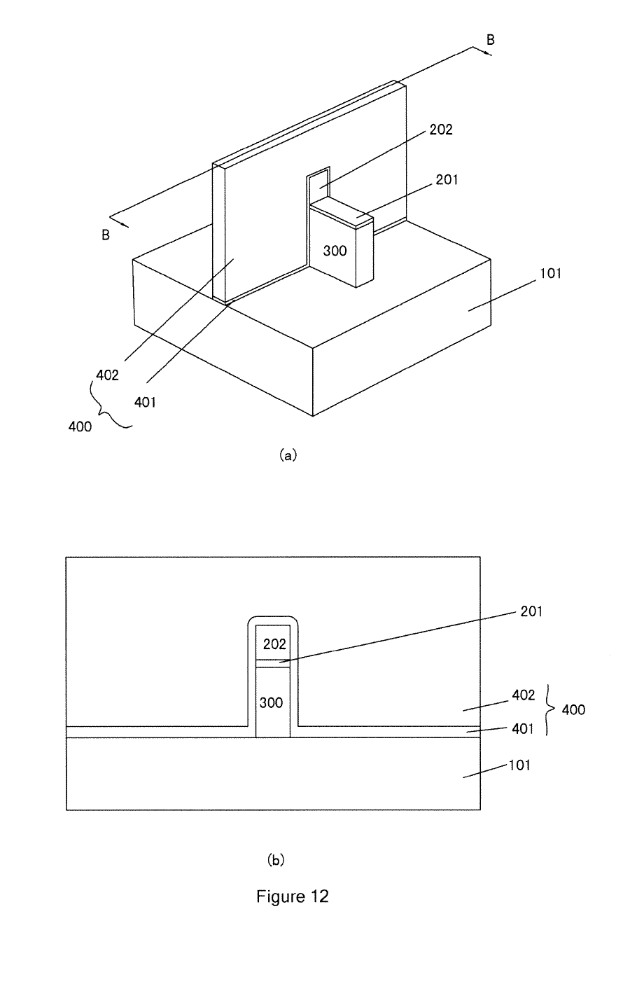

FIG. 12 shows a schematic view of the fourth step of the method for manufacturing a semiconductor device according to another exemplary embodiment of the invention. Therein FIG. 12(a) is a stereogram, and FIG. 12(b) is a cross-section view along the line B-B.

As shown in FIG. 12, a dummy gate stack 400 is formed. The dummy gate stack 400 is arranged on the threshold voltage adjusting layer 202, on the sidewalls of the active fin region 300 and on the insulating layer 101. The dummy gate stack 400 may comprise a dummy gate dielectric 401 and a dummy gate electrode 402 formed on the dummy gate dielectric 401.

In an example, the dummy gate stack may be formed in the following way: forming a dummy gate dielectric layer and a dummy gate electrode layer located on the dummy gate dielectric layer; and patterning the dummy gate electrode layer, the dummy gate dielectric layer and the threshold voltage adjusting layer. However, the invention is not limited thereto, and the dummy gate stack may also be formed in any other way. Optionally, the dummy gate electrode layer may be planarized after the dummy gate electrode layer is formed.

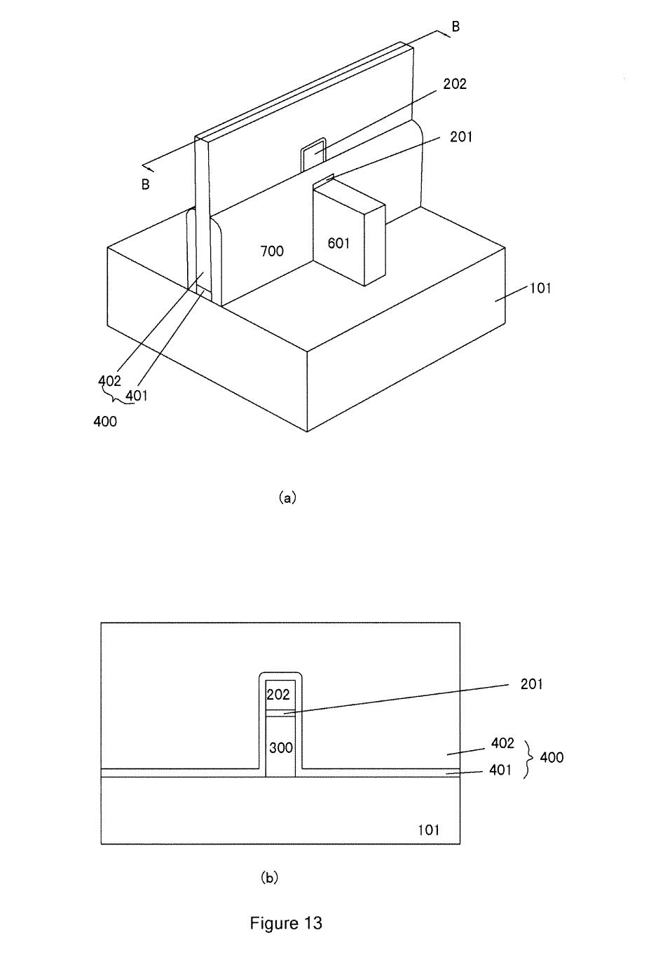

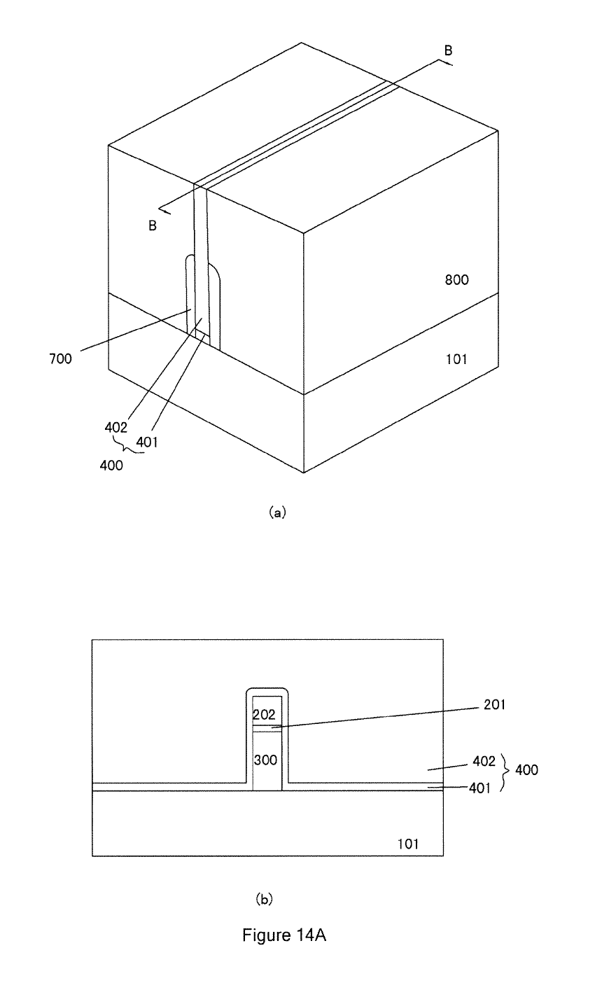

FIG. 13 shows a schematic view of the fifth step of the method for manufacturing a semiconductor device according to another exemplary embodiment of the invention. Therein FIG. 13(a) is a stereogram, and FIG. 13(b) is a cross-section view along the line B-B.

As shown in FIG. 13, a source region and a drain region are formed in the active fin region on both sides of the dummy gate stack 400 respectively. In the semiconductor device shown in FIG. 13, the structures on both sides of the dummy gate stack 400 may be symmetric. Therefore, in FIG. 13, the source region 601 located on one side of the dummy gate stack 400 is shown, while the drain region located on the other side of the dummy gate stack 400 is not shown.

In an example, the source region and the drain region may be formed by injecting ions into the active fin region on both sides of the dummy gate stack 400 respectively. However, the invention is not limited thereto, and the source region and the drain region may also be formed by any other process known to those skilled in the art.

Where a buffer layer 201 is formed, optionally, the buffer layer 201 on the part of the active fin region in which the source region and the drain region are to be formed may be removed before the source region and the drain region are formed.

Optionally, a spacer isolation layer 700 may be formed on both sides of the dummy gate stack 400, on the top and the sidewalls of the active fin region respectively before the source region and the drain region are formed. Where a buffer layer 201 is formed, the buffer layer 201 on the part of the active fin region in which the source region and the drain region are to be formed may be removed after the spacer isolation layer 700 is formed.

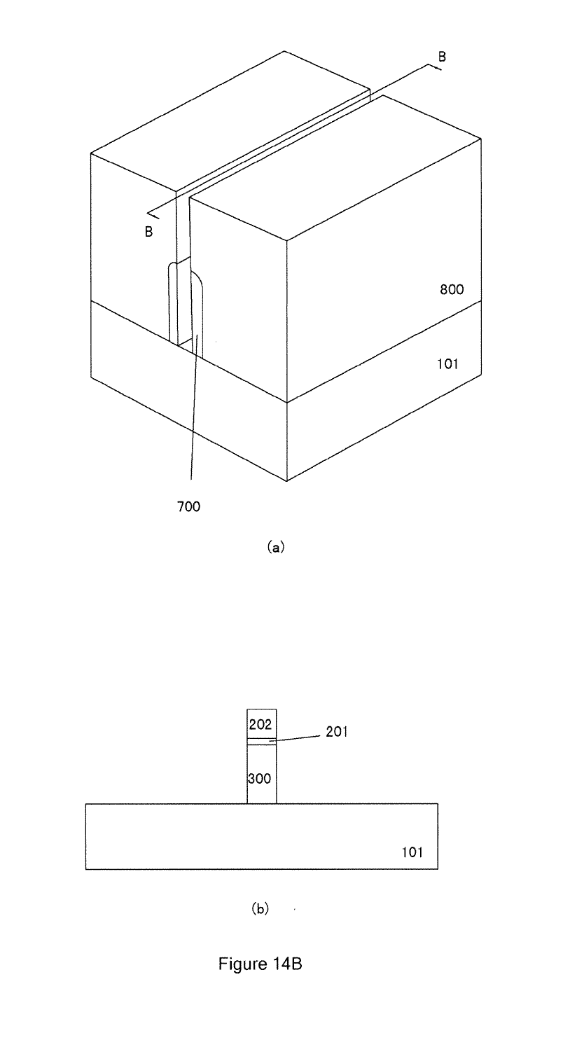

FIGS. 14A and 14B show schematic views of the sixth step of the method for manufacturing a semiconductor device according to another exemplary embodiment of the invention. Therein FIGS. 14A(a) and 14B(a) are stereograms, and FIG. 14A(b) and 14B(b) are cross-section views along the line B-B.

As shown in FIGS. 14A and 14B, the dummy gate stack is removed.

As an example, the dummy gate stack 400 may be removed in the following way: first, forming a dielectric layer 800 covering the dummy gate stack 400, as shown in FIG. 14A; and then removing the dummy gate stack 400 located in the dielectric layer 800, as shown in FIG. 14B. By removing the dummy gate stack 400, a gap may be formed in the dielectric layer 800. In an example, the dielectric layer 800 may be planarized so as to expose the dummy gate stack 400 after the dielectric layer 800 is formed.

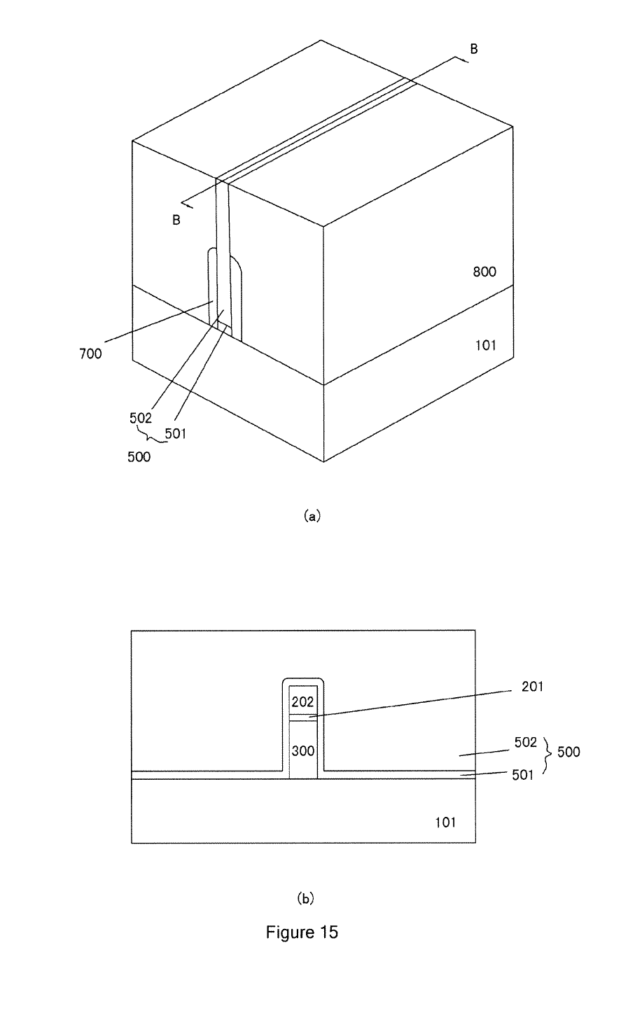

FIG. 15 shows a schematic view of the seventh step of the method for manufacturing a semiconductor device according to another exemplary embodiment of the invention. Therein FIG. 15(a) is a stereogram, and FIG. 15(b) is a cross-section view along the line B-B.

As shown in FIG. 15, a gate stack 500 is formed. The gate stack 500 is arranged on the threshold voltage adjusting layer 202, on the sidewalls of the active fin region 300 and on the insulating layer 101, and comprises a gate dielectric 501 and a gate electrode 502 formed on the gate dielectric 501.

As an example, the gate dielectric 501 may comprise a high-k dielectric material and the gate electrode 502 may comprise a metal.

In an example, the gate stack 500 may be formed by depositing a gate dielectric 501 on the threshold voltage adjusting layer 202, on the sidewalls of the active fin region 300 and on the insulating layer 101, and then depositing a gate electrode 502 on the gate dielectric 501. However, the invention is not limited thereto, and the gate stack 500 may be formed by any other process known to those skilled in the art.

In an example, the gate stack 500 may be formed in the dielectric layer 800 formed in the step of removing the dummy gate stack 400, as shown in FIG. 15(a). In particular, the gate stack 500 may be formed in the gap formed in the dielectric layer 800 by removing the dummy gate stack. The structure of the gate stack 500 in the dielectric layer 800 may be similar to the structure of the dummy gate stack 400 as shown in FIG. 13. The dielectric layer 800 may not necessarily be removed and instead used as an interlay dielectric of the semiconductor device.

Through the method as shown in FIGS. 9-15, a semiconductor device according to another exemplary embodiment of the invention is made, which comprises a threshold voltage adjusting layer. Through the threshold voltage adjusting layer, the threshold voltage of the semiconductor device may be adjusted, which provides a simple and convenient way capable of adjusting the threshold voltage of a semiconductor device comprising an active fin region.

Furthermore, in the method for manufacturing a semiconductor device as shown in FIGS. 9-15, first a dummy gate stack is formed and utilized to form a source region and a drain region, then the dummy gate stack is removed and a gate stack is formed. Such a procedure may protect the gate stack from being affected the process for forming the source region and the drain region, thereby improving the performance of the gate stack.

While the exemplary embodiments of the invention have been described in detail with reference to the drawings, such a description is to be considered illustrative or exemplary and not restrictive; the invention is not limited to the disclosed embodiments. Various embodiments described in the above and the claims may also be combined. Other variations to the disclosed embodiments can be understood and effected by those skilled in the art in practicing the claimed invention, from a study of the drawings, the disclosure, and the appended claims, which variations also fall within the protective scope of the invention.

In the claims, the word “comprising” does not exclude the presence of other elements or steps, and “a” or “an” does not exclude a plurality. The mere fact that certain measures are recited in mutually different dependent claims does not indicate that a combination of these measures cannot be used to advantage.

What is claimed is:

1. A semiconductor device, comprising:
an active fin region which is arranged on an insulating layer;
a threshold voltage adjusting layer arranged on top of the active fin region for adjusting the threshold voltage of the semiconductor device;
a gate stack which is arranged on the threshold voltage adjusting layer, on sidewalls of the active fin region and on the insulating layer, and comprises a gate dielectric and a gate electrode formed on the gate dielectric; and
a source region and a drain region formed in the active fin region on both sides of the gate stack, respectively.

2. The semiconductor device as claimed in claim 1, wherein the semiconductor device further comprises a buffer layer arranged between the top of the active fin region and the threshold voltage adjusting layer.

3. The semiconductor device as claimed in claim 2, wherein the buffer layer comprises an insulating material.

4. The semiconductor device as claimed in claim 1, wherein the threshold voltage adjusting layer comprises La, Er, Sc, Y, Ce, Pr, Nd, Pm, Sm, Eu, Gd, Tb, Dy, Ho, Tm, Yb, Lu, Sr, Al, Ga, In, Tl, or any other element for adjusting the threshold voltage.

5. The semiconductor device as claimed in claim 4, wherein the threshold voltage adjusting layer comprises a material selected from a group consisting of LaOₓ, ErOₓ, ScOₓ, YOₓ, CeOₓ, PrOₓ, NdOₓ, PmOₓ, SmOₓ, EuOₓ, GdOₓ, TbOₓ, DyOₓ, HoOₓ, TmOₓ, YbOₓ, LuOₓ, SrOₓ, Al₂O₃, Ga₂O₃, InOₓ, and TlOₓ, or any combination thereof.

6. The semiconductor device as claimed in claim 1, wherein the gate dielectric comprises a high-k dielectric material, and the gate electrode comprises a metal.

7. The semiconductor device as claimed in claim 1, wherein the gate stack further comprises a semiconductor layer formed on the gate electrode.

8. The semiconductor device as claimed in claim 7, wherein the semiconductor layer comprises polysilicon.

9. The semiconductor device as claimed in claim 1, wherein the semiconductor device further comprises a spacer isolation layer formed on both sides of the gate stack, on top and sidewalls of the active fin region respectively.

10. A method for manufacturing a semiconductor device, comprising:
providing a substrate, wherein the substrate comprises an insulating layer and a semiconductor layer arranged on the insulating layer;
forming a threshold voltage adjusting layer on the semiconductor layer, wherein the threshold voltage adjusting layer is used to adjust the threshold voltage of the semiconductor device;
patterning the threshold voltage adjusting layer and the semiconductor layer to form an active fin region on the insulating layer;
forming a gate dielectric layer and a gate electrode layer on the gate dielectric layer;
patterning the gate electrode layer, the gate dielectric layer and the threshold voltage adjusting layer to form a gate stack which is arranged on the threshold voltage adjusting layer, on sidewalls of the active fin region and on the insulating layer; and
forming a source region and a drain region in the active fin region on both sides of the gate stack respectively.

11. The method for manufacturing a semiconductor device as claimed in claim 10, further comprising forming a buffer layer on the semiconductor layer before the step of forming a threshold voltage adjusting layer.

12. The method for manufacturing a semiconductor device as claimed in claim 11, wherein the buffer layer is further patterned in the step of forming an active fin region.

13.-14. (canceled)

15. The method for manufacturing a semiconductor device as claimed in claim 10, wherein the gate dielectric layer comprises a high-k dielectric material, and the gate electrode layer comprises a metal.

16. The method for manufacturing a semiconductor device as claimed in claim 10, further comprising forming a further semiconductor layer on the gate electrode layer after the step of forming a gate dielectric layer and a gate electrode layer located on the gate dielectric layer.

17. The method for manufacturing a semiconductor device as claimed in claim 16, wherein the further semiconductor layer comprises polysilicon.

18. the method for manufacturing a semiconductor device as claimed in claim 16, wherein the further semiconductor layer is further patterned in the step of forming a gate stack.

19. The method for manufacturing a semiconductor device as claimed in claim 10, further comprising forming a spacer isolation layer on both sides of the gate stack, on top and sidewalls of the active fin region respectively before the step of forming a source region and a drain region.

20. (canceled)

21. A method for manufacturing a semiconductor device, comprising:
providing a substrate, wherein the substrate comprises an insulating layer and a semiconductor layer arranged on the insulating layer;
forming a threshold voltage adjusting layer on the semiconductor layer, wherein the threshold voltage adjusting layer is used to adjust the threshold voltage of the semiconductor device;
patterning the threshold voltage adjusting layer and the semiconductor layer to form an active fin region on the insulating layer;
forming a dummy gate stack on the threshold voltage adjusting layer, on sidewalls of the active fin region and on the insulating layer;
forming a source region and a drain region in the active fin region on both sides of the dummy gate stack respectively;
removing the dummy gate stack; and
forming a gate stack on the threshold voltage adjusting layer, on sidewalls of the active fin region and on the insulating layer, wherein the gate stack comprises a gate dielectric and a gate electrode formed on the gate dielectric.

22. The method for manufacturing a semiconductor device as claimed in claim 21, further comprising forming a buffer layer on the semiconductor layer before the step of forming a threshold voltage adjusting layer.

23. The method for manufacturing a semiconductor device as claimed in claim 22, wherein the buffer layer is further patterned in the step of forming an active fin region.

24.-25. (canceled)

26. The method for manufacturing a semiconductor device as claimed in claim 21, wherein gate dielectric comprises a high-k dielectric material, and the gate electrode comprises a metal.

27. The method for manufacturing a semiconductor device as claimed in claim 21, wherein the step of forming a dummy gate stack comprises:
forming a dummy gate dielectric layer and a dummy gate electrode layer on the dummy gate dielectric layer; and
patterning the dummy gate electrode layer, the dummy gate dielectric layer and the threshold voltage adjusting layer.

28. The method for manufacturing a semiconductor device as claimed in claim 27, further comprising planarizing the dummy gate electrode layer after the dummy gate electrode layer is formed.

29. The method for manufacturing a semiconductor device as claimed in claim 21, wherein the step of removing the dummy gate stack comprises:
forming a dielectric layer to cover the dummy gate stack; and
removing the dummy gate stack located in the dielectric layer.

30. The method for manufacturing a semiconductor device as claimed in claim 29, wherein after the dielectric layer is formed, the method further comprises planarizing the dielectric layer so as to expose the dummy gate stack.

31. The method for manufacturing a semiconductor device as claimed in claim 21, further comprising forming a spacer isolation layer on both sides of the dummy gate stack, on top and sidewalls of the active fin region respectively before the step of forming a source region and a drain region.
